(19) United States
(12) Patent Application Publication
(10) Pub. No.: US 2008/0268567 A1
(43) Pub. Date: Oct. 30, 2008

(54) Method for fabricating organic light emitting display

(75) Inventors: Shih-Chang Wang, Miao-Li (TW); Jung-Lung Huang, Miao-Li (TW)

Correspondence Address: WEI TE CHUNG;FOXCONN INTERNATIONAL, INC., 1650 MEMOREX DRIVE, SANTA CLARA, CA, 95050, US

(73) Assignee: INNOLUX DISPLAY CORP.

(21) Appl. No.: 12/150,384

(22) Filed: Apr. 28, 2008

(30) Foreign Application Priority Data
Apr. 27, 2007 (CN) 200710074232.1

(51) Int. Cl. H01L 51/56

(52) U.S. Cl. 438/99; 257/E51.018

(57) ABSTRACT

An exemplary method for fabricating an OLED (20) is provided. The method includes: providing an insulative substrate; forming a first electrode on the substrate, the first electrode being a conductive thin film; forming a second electrode on the first electrode, comprising providing an oxygen-containing oxidizing gas with a material used to form the second electrode; patterning the first and second electrodes to form an anode on the substrate; forming a hole injection layer on the anode; forming a hole transfer layer on the hole injection layer; forming an organic light emitting layer on the hole transfer layer; forming an electron transfer layer on the organic light emitting layer; forming an electron injection layer on the electron transfer layer; and forming a cathode on the electron injection layer.

### BACKGROUND

1. Field of the Invention

The present invention relates to methods for fabricating organic light emitting displays (OLEDs), and particularly to a method for fabricating an OLED that has an anode layer with high, uniform work function.

2. General Background

Organic light emitting displays (OLEDs) provide high brightness and a wide viewing angle. Because OLEDs are self-luminous, they do not require a backlight, and can be effectively employed in electronic devices that are used even under relatively dark ambient conditions.

Referring to FIG. 2, a typical OLED 10 is shown. The OLED 10 includes a substrate 11, and a stack formed on the substrate 11. The stack includes an anode 12, a hole injection layer (HIL) 13, a hole transfer layer (HTL) 14, an organic light emitting layer 15, an electron transfer layer (ETL) 16, an electron injection layer (EIL) 17, and a cathode 18, which are formed on the substrate 11 in that order from bottom to top.

The working principle of the OLED 10 is as follows. A forward-bias voltage is applied between the anode 12 and the cathode 18. Holes of the anode 12 are injected into the organic light organic light emitting layer 15 via the hole injection layer 13 and the hole transfer layer 14 under the forward-bias voltage. Electrons of the cathode 18 are also injected into the organic light emitting layer 15 via the electron injection layer 17 and the electron transfer layer 16 under the forward-bias voltage. The holes from the anode 12 and the electrons from the cathode 18 combine in the organic light emitting layer 15 to excite photons. Thus, the OLED 10 emits light.

In order that the holes of the anode 12 are injected into the organic light emitting layer 15, an energy barrier between the anode 12 and the organic light emitting layer 15 must be overcome by applying the forward-bias voltage. In general, the larger a work function of the anode 12, the lower the energy barrier that needs to be overcome, and the lower the forward-bias voltage that is needed to drive the OLED 10 to emit light. In order to increase the work function of the anode 12, manufacturers generally adopt an indium tin oxide (ITO) film having a large work function when fabricating the anode 12. A surface of the ITO film is treated with oxygen plasma or ultraviolet radiation/ozone to form a thin film on the ITO film. As a result of the surface treatment, an oxygen content of the ITO film is increased, and therefore the work function of the anode 12 is increased.

Referring to FIG. 3, this shows details of the anode 12 after such treatment. The anode 12 includes a first electrode 121, and a second electrode 122 formed on the first electrode 121. A thickness of the second electrode 122 is much less than a thickness of the first electrode 121. The second electrode 122 is the thin film formed by the surface treatment process of the first electrode 121. Therefore, an oxygen content of the second electrode 122 is much greater than an oxygen content of the first electrode 121.

The surface treatment process only increases the oxygen content of the thin second electrode 122, and essentially cannot increase an oxygen content of the whole anode 12. Therefore, the advantageous result of the surface treatment process is limited. In addition, if oxygen plasma is used in the surface treatment process, the thin film produced is liable to be non-uniform. In such case, the anode 12 typically has a non-uniform work function distribution. Thus when the forward-bias is applied to the OLED 10, the light emission of the OLED 10 is liable to be non-uniform.

Therefore, a new method for fabricating an OLED that can overcome the above-described problems is desired.

### SUMMARY

In one preferred embodiment, a method for fabricating an OLED is provided. The method includes: providing an insulative substrate; forming a first electrode on the substrate, the first electrode being a conductive thin film; forming a second electrode on the first electrode, comprising providing an oxygen-containing oxidizing gas with a material used to form the second electrode; patterning the first and second electrodes to form an anode on the substrate; forming a hole injection layer on the anode; forming a hole transfer layer on the hole injection layer; forming an organic light emitting layer on the hole transfer layer; forming an electron transfer layer on the organic light emitting layer; forming an electron injection layer on the electron transfer layer; and forming a cathode on the electron injection layer.

Other novel features and advantages will become more apparent from the following detailed description when taken in conjunction with the accompanying drawings. In the drawings, all the views are schematic.

### BRIEF DESCRIPTION OF THE DRAWINGS

FIG. 1 is a flow chart summarizing a method for fabricating an OLED according to an exemplary embodiment of the present invention.

FIG. 2 is a side view of a conventional OLED, the OLED including an anode.

FIG. 3 is a side view showing details of the anode of FIG. 2.

### DETAILED DESCRIPTION OF PREFERRED EMBODIMENTS

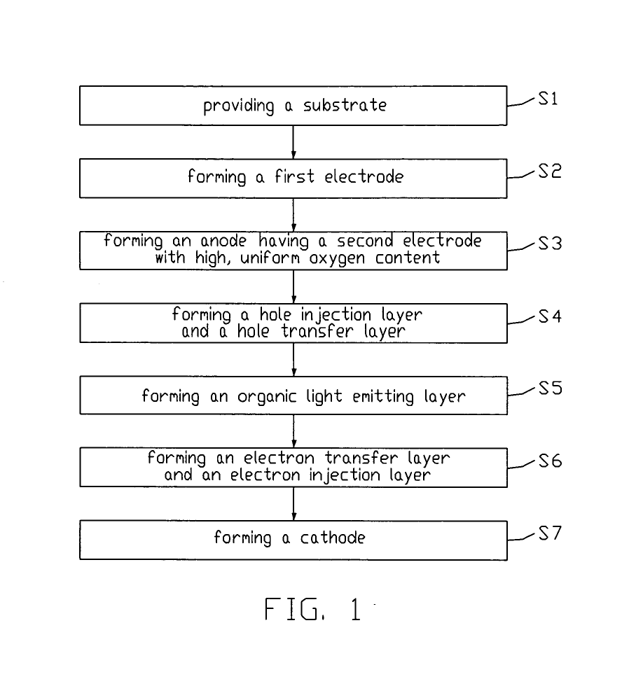

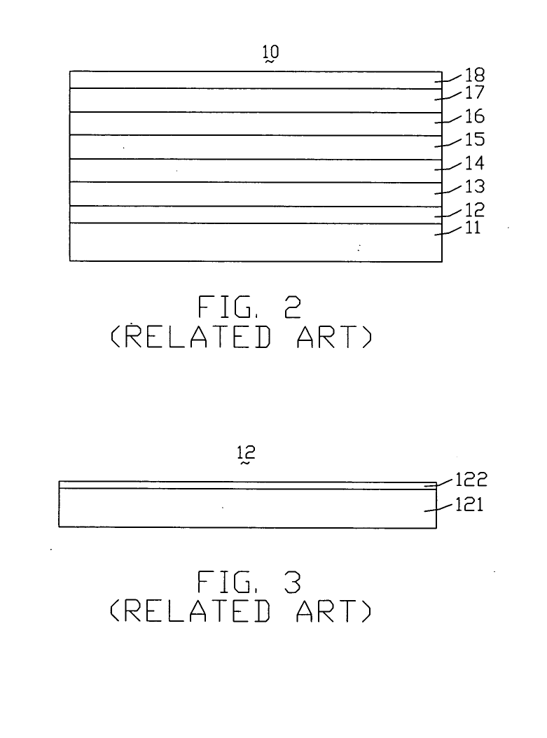

Referring to FIG. 1, this is a flow chart summarizing a method for fabricating an OLED according to an exemplary embodiment of the present invention. The method includes: step S1, providing a substrate; step S2, forming a first electrode; step S3, forming an anode having a second electrode with high, uniform oxygen content; step S4, forming a hole injection layer and a hole transfer layer; step S5, forming an organic light emitting layer; step S6, forming an electron transfer layer and an electron injection layer; and step S7, forming a cathode.

In step S1, a transparent substrate is provided. The substrate is used to support the OLED to be fabricated. The material of the substrate can for example be glass, quartz, or another suitable transparent insulative material.

In step S2, a first electrode is formed on the substrate by a deposition method. A desired thickness of the first electrode is obtained by appropriately fixing a deposition speed and a deposition time. The thickness is preferably equal to 1.3×10⁻⁷ meters. The material of the first electrode can be indium zinc oxide (IZO), ITO, or another transparent conductive material having a high work function. The deposition method can, for example, be a sputtering method.

In step S3, a second electrode is deposited on the first electrode. The material of the second electrode can be indium zinc oxide (IZO), ITO, or another transparent conductive material having a high work function. The second electrode can be deposited by, for example, a sputtering method. During the deposition process, a high oxygen content and strongly oxidizing gas is provided to increase an oxygen content of the second electrode. When the transparent conductive film has grown to a predetermined thickness, the deposition and the gas supply are stopped. Then, the first and second electrodes are patterned to cooperatively constitute an anode. The patterning process of the first and second electrodes can include: coating a photo-resist layer on the second electrode; exposing the photo-resist layer through a photo-mask; developing the exposed photo-resist layer to form a photo-resist pattern on the second electrode; etching the first and second electrodes using the photo-resist pattern as a mask; and removing the photo-resist pattern, whereby the anode is obtained. The predetermined thickness of the second electrode is preferably equal to 2×10⁻⁸ meters. The oxidizing gas can be oxygen, water vapor, or a mixture of these. The oxygen content of the second electrode is controllable according to requirements by controlling a flow rate of the oxidizing gas. The thicknesses of the first and second electrodes can be varied according to particular requirements. Further, when the material of the second electrode is the same as the material of the first electrode, the process of depositing the second electrode can be a continuation of the process of depositing the first electrode, with the gas being introduced as soon as the first electrode has reached a desired thickness.

In step S4, the anode is rinsed of impurities, is ultrasonic cleaned, and is cleaned with an organic solvent such as acetone, ethanol, and so on. An organic solvent vapor degreasing process is performed, and then the anode is repeatedly rinsed with deionized water. After that, a transparent hole injection layer and a transparent hole transfer layer are formed on the anode, in that order from bottom to top. The method for forming the two layers can, for example, be a vapor deposition method. The material of the hole injection layer is copper phthalocyanine (CuPc). The material of the hole transfer layer is an aromatic polyamine compound, such as polyaniline or triarylamine derivative. The hole injection layer and the hole transfer layer are configured to reduce a driving voltage of the OLED, and improve the stability of the OLED.

In step S5, a transparent organic light emitting layer is formed on the hole transfer layer. The material of the organic light emitting layer can be a macromolecular electroluminescence compound, or a micromolecular electroluminescence compound. If a macromolecular electroluminescence compound is used, the organic layer is formed by a spin-coating method or an ink jet printing method. The macromolecular electroluminescence compound can for example be para-phenylenevinylene (PPV). If a micromolecular electroluminescence compound is used, the organic layer is formed by a vacuum vapor deposition method. The micromolecular electroluminescence compound can for example be diamine. The method for forming the organic light emitting layer can, for example, be a chemical vapor deposition method.

In step S6, a transparent electron transfer layer and a transparent electron injection layer are deposited on the organic light emitting layer, in that order from bottom to top. The material of the electron transfer layer can be an aromatic compound having a large conjugate plane. The material of the electron injection layer can be an alkali metal, an alkali metal compound such as lithium fluoride, an alkaline-earth metal such as calcium or magnesium, or an alkaline-earth metal compound.

In step S7, a transparent cathode is deposited on the electron injection layer, whereby the OLED is obtained. The cathode can be a transparent thin film, and typically has a thickness in the range from 5×10⁻⁹ meters to 3×10⁻⁸ meters. Because the cathode is very thin, the cathode has high transmittance and does not significantly impede the emission efficiency of the OLED. The cathode can be a multilayer structure which includes at least two metal layers, such as a lithium/aluminum/argentine multilayer structure, a calcium/aluminum multilayer structure, or a magnesium/argentine multilayer structure.

In summary, during the anode deposition step, the strongly oxidizing gas is provided to increase the oxygen content of an interior and a surface of the anode, such that the anode has a large work function. In addition, because the flow rate of the oxidizing gas is controllable, the oxygen content of the second electrode of the anode can be uniform. Therefore the work function of the anode is uniformly distributed, and the light emission of the OLED is correspondingly uniform.

It is to be further understood that even though numerous characteristics and advantages of the present embodiments have been set out in the foregoing description, together with details of the steps and functions of the embodiments, the disclosure is illustrative only; and that changes may be made in detail, especially in matters of arrangement of parts within the principles of the invention to the full extent indicated by the broad general meaning of the terms in which the appended claims are expressed.

What is claimed is:

1. A method for fabricating an organic light emitting display (OLED), the method comprising:
providing an insulative substrate;
forming a first electrode on the substrate, the first electrode being a conductive thin film;
forming a second electrode on the first electrode, comprising providing an oxygen-containing oxidizing gas with a material used to form the second electrode;
patterning the first and second electrodes to form an anode on the substrate;
forming a hole injection layer on the anode;
forming a hole transfer layer on the hole injection layer;
forming an organic light emitting layer on the hole transfer layer;
forming an electron transfer layer on the organic light emitting layer;
forming an electron injection layer on the electron transfer layer; and
forming a cathode on the electron injection layer.

2. The method in claim 1, wherein the gas comprises one of oxygen, water vapor, and a mixture of oxygen and water vapor.

3. The method in claim 1, wherein each of the first and second electrodes is made from one of indium zinc oxide and indium tin oxide.

4. The method in claim 1, wherein a thickness of the first electrode is approximately equal to 1.3×10⁻⁷ meters.

5. The method in claim 1, wherein a thickness of the second electrode is approximately equal to 2×10⁻⁸ meters.

6. The method in claim 1, wherein the substrate is made from glass or quartz.

7. The method in claim 1, wherein the first electrode is formed by a sputtering method.

8. The method in claim 1, wherein the organic light emitting layer is made from a macromolecular electroluminescence compound.

9. The method in claim 8, wherein the macromolecule electroluminescence compound is poly-phenylenevinylene.

10. The method in claim 8, wherein the organic light emitting layer is formed by a spin-coating method or an ink jet printing method.

11. The method in claim 1, wherein the organic light emitting layer is made from a micromolecular electroluminescence compound.

12. The method in claim 11, wherein the micromolecular electroluminescence compound is diamine.

13. The method in claim 11, wherein the organic light emitting layer is formed by a vacuum vapor deposition method.

14. The method in claim 1, wherein the hole injection layer is made from copper phthalocyanine (CuPc).

15. The method in claim 1, wherein the hole transfer layer is made from one of polyaniline and triarylamine derivative.

16. The method in claim 1, wherein a thickness of the cathode is in the range from 5×10⁻⁹ meters to 3×10⁻⁸ meters.

17. The method in claim 1, wherein the cathode comprises one of a lithium/aluminum/argentine multilayer structure, a calcium/aluminum multilayer structure, and a magnesium/argentine multilayer structure.

18. The method in claim 1, wherein the electron transfer layer is made from an aromatic compound.

19. The method in claim 1, wherein the electron injection layer is made from an alkali metal, an alkali metal compound, an alkaline-earth metal, or an alkaline-earth metal compound.

20. A method for fabricating an organic light emitting display (OLED), the method comprising:
providing an insulative substrate;
depositing transparent conductive material on the substrate;
introducing an oxygen-containing oxidizing gas into the process of depositing the transparent conductive material when the deposited transparent conductive material has reached a first predetermined thickness;
stopping the process of depositing and the providing of the gas when the deposited transparent conductive material has reached a second predetermined thickness, the second predetermined thickness being greater than the first predetermined thickness;
patterning the deposited transparent conductive material to form an anode;
forming a hole injection layer on the anode;
forming a hole transfer layer on the hole injection layer;
forming an organic light emitting layer on the hole transfer layer;
forming an electron transfer layer on the organic light emitting layer;
forming an electron injection layer on the electron transfer layer; and
forming a cathode on the electron injection layer.
